(19) United States
(12) Patent Application Publication
(10) Pub. No.: US 2012/0236662 A1
(43) Pub. Date: Sep. 20, 2012

(54) WORD-LINE-POTENTIAL CONTROL CIRCUIT

(75) Inventors: Miyako Shizuno, Yokohama-shi (JP); Osamu Hirabayashi, Suginami-ku (JP)

(73) Assignee: KABUSHIKI KAISHA TOSHIBA, Tokyo (JP)

(21) Appl. No.: 13/239,213

(22) Filed: Sep. 21, 2011

(30) Foreign Application Priority Data
Mar. 17, 2011 (JP) 2011-059262

(51) Int. Cl. G11C 8/08; G11C 7/00

(52) U.S. Cl. 365/189.15

(57) ABSTRACT

According to one embodiment, in a memory cell array, a plurality of memory cells is arranged in an array. A read circuit reads out data from the memory cells. A word line driver drives a word line of the memory cells. A characteristic control unit controls a specific characteristic of the memory cells. A word-line-potential adjusting unit adjusts a potential of the word line based on a distribution of the characteristic when the specific characteristic of the memory cells is controlled.

### CROSS-REFERENCE TO RELATED APPLICATIONS

This application is based upon and claims the benefit of priority from Japanese Patent Application No. 2011-59262, filed on Mar. 17, 2011; the entire contents of which are incorporated herein by reference.

### FIELD

Embodiments described herein relate generally to a word-line-potential control circuit.

### BACKGROUND

For reducing power consumption of SRAMs, reduction of a power supply voltage of SRAMs is performed. However, when the power supply voltage of SRAMs is reduced, an operation margin of SRAMs decreases, so that it is desired to correct a word line potential according to manufacturing variations, an operating temperature, and the like of SRAMs.

### BRIEF DESCRIPTION OF THE DRAWINGS

FIG. 1 is a block diagram illustrating a schematic configuration of a word-line-potential control circuit according to a first embodiment;

FIG. 2 is a diagram illustrating an example of a circuit configuration of a memory cell in FIG. 1;

FIG. 3 is a diagram illustrating an example of a configuration of a word line driver circuit in FIG. 1 for one word line;

FIG. 4 is a block diagram illustrating a schematic configuration of a source potential control unit in FIG. 1;

FIG. 5 is a flowchart illustrating an operation of the word-line-potential control circuit in FIG. 1;

FIG. 6 is a diagram illustrating distributions of the number of data inversions with respect to a source potential before and after word line potential adjustment in the word-line-potential control circuit in FIG. 1;

FIG. 7 is a diagram illustrating a relationship between a word line potential, process conditions, and temperature of the word-line-potential control circuit in FIG. 1, and SNM data;

FIG. 8 is a diagram illustrating changes in μSNM and σSNM when the word line potential, the process conditions, and the temperature of the word-line-potential control circuit in FIG. 1 are changed;

FIG. 9 is a flowchart illustrating an operation of a word-line-potential control circuit according to a second embodiment;

FIG. 10 is a block diagram illustrating a schematic configuration of a word-line-potential control circuit according to a third embodiment; and

FIG. 11 is a flowchart illustrating an operation of the word-line-potential control circuit in FIG. 10.

### DETAILED DESCRIPTION

In general, according to a word-line-potential control circuit of embodiments, a memory cell array, a read circuit, a word line driver, a characteristic control unit, and a word-line-potential adjusting unit are included. In the memory cell array, a plurality of memory cells is arranged in an array. The read circuit reads out data from the memory cells. The word line driver drives a word line of the memory cells. The characteristic control unit controls a specific characteristic of the memory cells. The word-line-potential adjusting unit adjusts a potential of the word line based on a distribution of the characteristic when the specific characteristic of the memory cells is controlled.

A word-line-potential control circuit according to the embodiments will be explained below with reference to the drawings. The present invention is not limited to these embodiments.

### First Embodiment

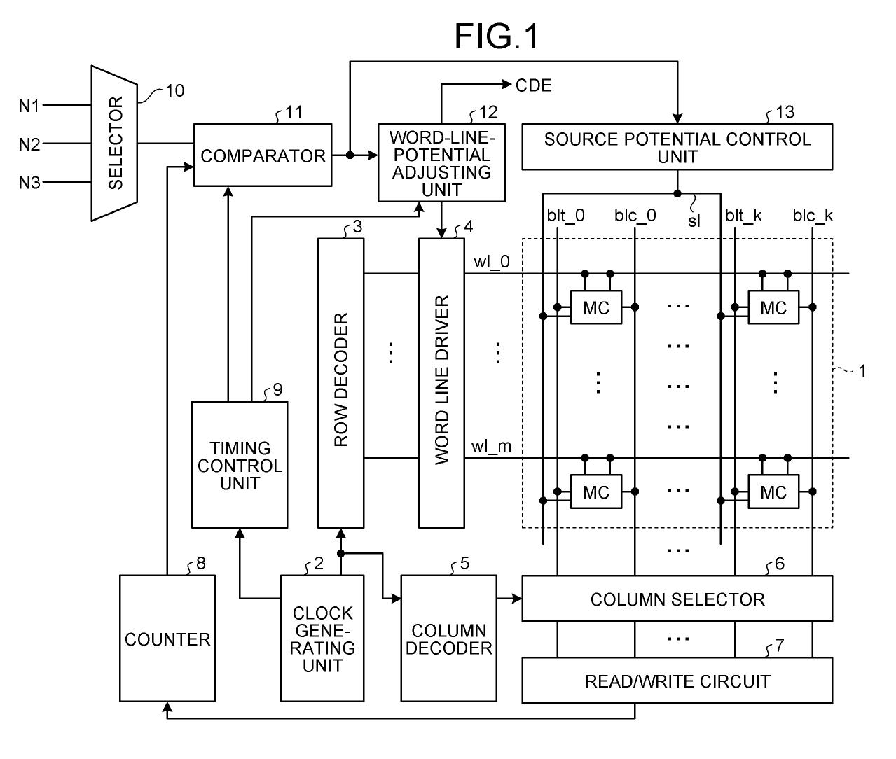

FIG. 1 is a block diagram illustrating a schematic configuration of a word-line-potential control circuit according to the first embodiment.

In FIG. 1, the word-line-potential control circuit includes a memory cell array 1, a clock generating unit 2, a row decoder 3, a word line driver 4, a column decoder 5, a column selector 6, a read/write circuit 7, a counter 8, a timing control unit 9, a selector 10, a comparator 11, a word-line-potential adjusting unit 12, and a source potential control unit 13.

In the memory cell array 1, memory cells MC are arranged in a matrix manner in a row direction and a column direction. The memory cell MC can complementarily store therein data, and for example, an SRAM cell can be used for the memory cell MC. Moreover, in the memory cell array 1, word lines wl_0 to wl_m (m is a positive integer) that perform row selection of the memory cells MC are provided for rows, respectively, and bit lines blt_0 to blt_k and blc_0 to blc_k (k is a positive integer) that perform column selection of the memory cells MC are provided for columns, respectively. The number of cells of the memory cell array 1 can be set to, for example, 2K bits.

The clock generating unit 2 can generate a clock to be a reference of reading and writing. The row decoder 3 can select any of the word lines wl_0 to wl_m made to perform row selection of the memory cells MC based on a row address. The word line driver 4 can drive any of the word lines wl_0 to wl_m selected in the row decoder 3.

The column decoder 5 can select any of the bit lines blt_0 to blt_k and blc_0 to blc_k made to perform column selection of the memory cells MC based on a column address. The column selector 6 can connect any of the bit lines blt_0 to blt_k and blc_0 to blc_k selected in the column decoder 5 to the read/write circuit 7. As a read circuit, a sense amplifier can be used, which detects data stored in the memory cells MC based on signals read out from the memory cells MC on the bit lines blt_0 to blt_k and blc_0 to blc_k. As a write circuit, a write amplifier can be used, which complementarily drives the bit lines blt_0 to blt_k and the bit lines blc_0 to blc_k with each other according to write data.

The counter 8 can count the number of inversions of data read out from the memory cells MC. The timing control unit 9 can control comparison timing by the comparator 11 and word-line-potential adjusting timing by the word-line-potential adjusting unit 12. The selector 10 can switch between expectations N1 to N3 and output the expectation to the comparator 11. The comparator 11 can compare a count result by the counter 8 with the expectations N1 to N3.

The word-line-potential adjusting unit 12 can adjust the potential of the word lines wl_0 to wl_m based on a characteristic distribution when specific characteristics of the memory cells MC are controlled. As the specific characteristics of the memory cells MC, stability when data is stored in the memory cells MC can be exemplified. As an index indicating stability of the memory cells MC, for example, a static noise margin SNM can be used.

The source potential control unit 13 can control a source potential SCFV of the memory cells MC via a source line sl. Moreover, the source potential control unit 13 can obtain the distribution of the number of data inversions with respect to the source potential SCFV from two points at which the number of inversions of data read out from the memory cells MC matches the expectations N1 and N2 when the source potential SCFV is swept. This source potential SCFV is highly correlated with the static noise margin SNM. Therefore, the source potential SCFV can be used as a control value that controls the static noise margin SNM of the memory cells MC. Moreover, sweep of the source potential SCFV in this specification means to change the source potential SCFV.

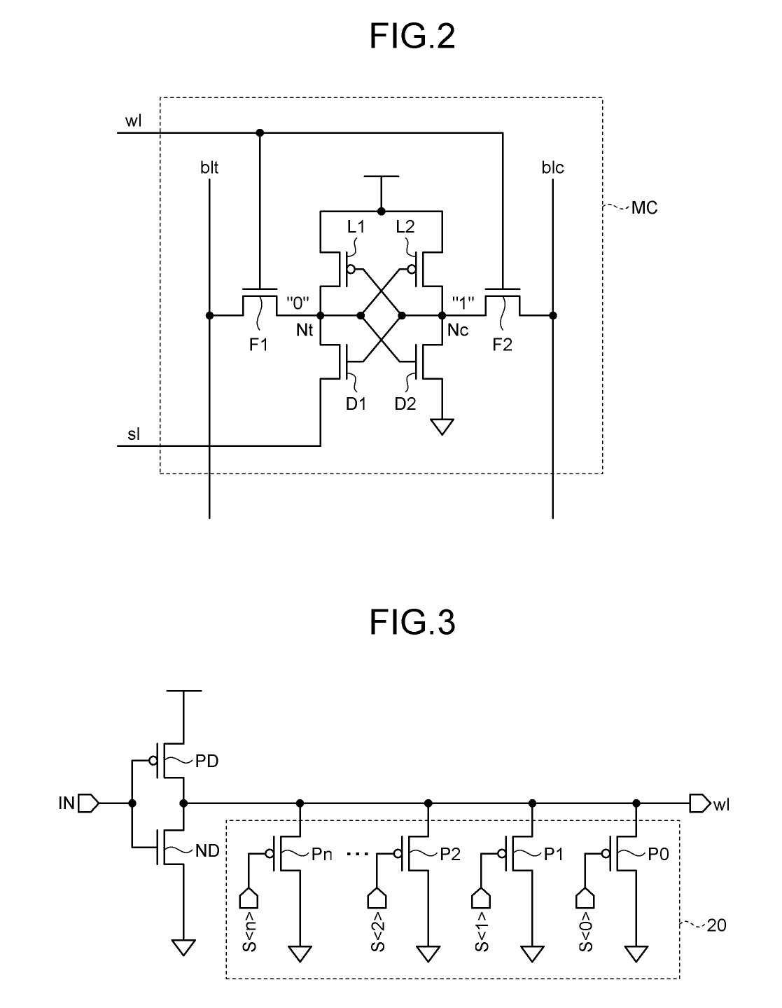

FIG. 2 is a diagram illustrating an example of a circuit configuration of the memory cell in FIG. 1.

In FIG. 2, the memory cell MC includes a pair of drive transistors D1 and D2, a pair of load transistors L1 and L2, and a pair of transfer transistors F1 and F2. P-channel field-effect transistors can be used as the load transistors L1 and L2, and N-channel field-effect transistors can be used as the drive transistors D1 and D2 and the transfer transistors F1 and F2.

The drive transistor D1 and the load transistor L1 are connected in series with each other to form a CMOS inverter and the drive transistor D2 and the load transistor L2 are connected in series with each other to form a CMOS inverter. The outputs and the inputs of a pair of the CMOS inverters are cross-coupled to each other to form a flip-flop. A word line wl is connected to the gates of the transfer transistors F1 and F2.

The connection point of the drain of the drive transistor D1 and the drain of the load transistor L1 can form a storage node Nt and the connection point of the drain of the drive transistor D2 and the drain of the load transistor L2 can form a storage node Nc.

The bit line blt is connected to the storage node Nt via the transfer transistor F1. The bit line blc is connected to the storage node Nc via the transfer transistor F2. The sources of the load transistors L1 and L2 are connected to the power supply potential, the source of the drive transistor D1 is connected to the source line sl, and the source of the drive transistor D2 is connected to the ground potential. The source potential SCFV can be applied to the source line sl via the source potential control unit 13 in FIG. 1.

FIG. 3 is a diagram illustrating an example of a configuration of a word line driver circuit in FIG. 1 for one word line.

In FIG. 3, the word line driver 4 includes a P-channel field-effect transistor PD, an N-channel field-effect transistor ND, and a word-line-potential variable unit 20. The word-line-potential variable unit 20 includes P-channel field-effect transistors P0 to Pn (n is a positive integer). The P-channel field-effect transistor PD and the N-channel field-effect transistor ND are connected in series with each other to form a CMOS inverter. The word line wl is connected to the connection point of the P-channel field-effect transistor PD and the N-channel field-effect transistor ND and the P-channel field-effect transistors P0 to Pn are connected to the word line wl in parallel with each other. Control signals S<0> to S<n> are input to the gates of the P-channel field-effect transistors P0 to Pn, respectively.

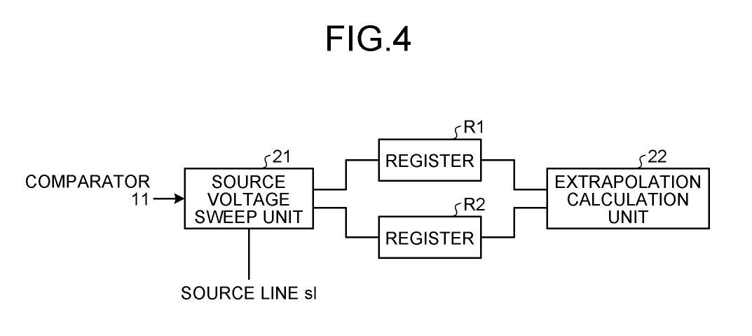

FIG. 4 is a block diagram illustrating a schematic configuration of the source potential control unit in FIG. 1.

In FIG. 4, the source potential control unit 13 includes a source voltage sweep unit 21, an extrapolation calculation unit 22, and registers R1 and R2. The source voltage sweep unit 21 can sweep the source potential SCFV. The register R1 can store the value of the source potential SCFV when a count result by the counter 8 matches the expectation N1. The register R2 can store the value of the source potential SCFV when a count result by the counter 8 matches the expectation N2. The extrapolation calculation unit 22 can estimate the distribution of the number of data inversions of the memory cells MC with respect to the source potential SCFV based on the values of the source potential SCFV stored in the registers R1 and R2.

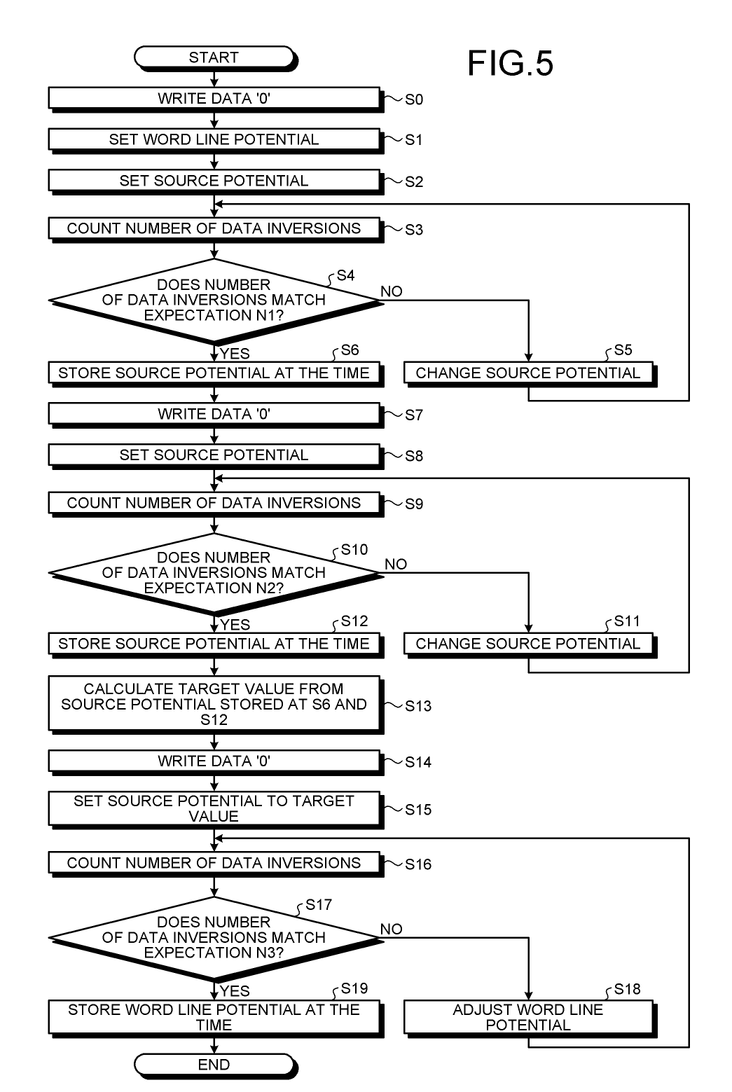

FIG. 5 is a flowchart illustrating an operation of the word-line-potential control circuit in FIG. 1.

In FIG. 5, data ‘0’ is written in all of the memory cells MC of the memory cell array 1 via the read/write circuit 7 in FIG. 1 (S0). At this time, as shown in FIG. 2, the data ‘0’ is stored in the storage node Nt and data ‘1’ is stored in the storage node Nc.

Next, in the word-line-potential adjusting unit 12, the word line potential is set to the initial value (S1). The initial value of the word line potential may be any value, however, is preferably set to the highest voltage available in the word-line-potential control circuit for shortening the word-line-potential adjusting time.

Next, in the source potential control unit 13, the source potential SCFV is set to the initial value (S2). The initial value of the source potential SCFV may be any value and, for example, can be set to the ground potential.

Next, data is read out from all of the memory cells MC of the memory cell array 1 via the read/write circuit 7 in FIG. 1. Then, in the counter 8, the number of inversions of data read out from the memory cells MC is counted (S3) and is output to the comparator 11. Moreover, in the selector 10 in FIG. 1, the expectation N1 is selected and is output to the comparator 11. Then, in the comparator 11, the number of inversions of data read out from the memory cells MC is compared with the expectation N1 (S4) and the comparison result thereof is sent to the source potential control unit 13.

Then, in the source potential control unit 13, when the number of inversions of data read out from the memory cells MC does not match the expectation N1, the source potential SCFV is changed via the source voltage sweep unit 21 in FIG. 4 (S5). Thereafter, the processes at Steps S3 to S5 are repeated until the number of inversions of data read out from the memory cells MC matches the expectation N1.

Then, when the number of inversions of data read out from the memory cells MC matches the expectation N1, the source potential SCFV at the time is stored in the register R1 in FIG. 4 (S6).

Next, data ‘0’ is written in all of the memory cells MC of the memory cell array 1 via the read/write circuit 7 in FIG. 1 (S7). Next, in the source potential control unit 13, the source potential SCFV is set to the initial value (S8).

Next, data is read out from all of the memory cells MC of the memory cell array 1 via the read/write circuit 7 in FIG. 1. Then, in the counter 8, the number of inversions of data read out from the memory cells MC is counted (S9), and is output to the comparator 11. Moreover, in the selector 10 in FIG. 1, the expectation N2 is selected and is output to the comparator 11. Then, in the comparator 11, the number of inversions of data read out from the memory cells MC is compared with the expectation N2 (S10) and the comparison result thereof is sent to the source potential control unit 13.

Then, in the source potential control unit 13, when the number of inversions of data read out from the memory cells MC does not match the expectation N2, the source potential SCFV is changed via the source voltage sweep unit 21 in FIG. 4 (S11). Thereafter, the processes at Steps S9 to S11 are repeated until the number of inversions of data read out from the memory cells MC matches the expectation N2.

Then, when the number of inversions of data read out from the memory cells MC matches the expectation N2, the source potential SCFV at the time is stored in the register R2 in FIG. 4 (S12).

Next, in the extrapolation calculation unit 22 in FIG. 4, the distribution of the number of data inversions of the memory cells MC with respect to the source potential SCFV is estimated based on the values of the source potential SCFV stored in the registers R1 and R2. Then, the target value of the source potential SCFV is calculated so that a predetermined margin is obtained based on the distribution of the number of data inversions of the memory cells MC with respect to the source potential SCFV (S13).

Next, data ‘0’ is written in all of the memory cells MC of the memory cell array 1 via the read/write circuit 7 in FIG. 1 (S14). Next, in the source potential control unit 13, the source potential SCFV is set to the target value (S15).

Next, data is read out from all of the memory cells MC of the memory cell array 1 via the read/write circuit 7 in FIG. 1. Then, in the counter 8, the number of inversions of data read out from the memory cells MC is counted (S16) and is output to the comparator 11. Moreover, in the selector 10 in FIG. 1, the expectation N3 is selected and is output to the comparator 11. Then, in the comparator 11, the number of inversions of data read out from the memory cells MC is compared with the expectation N3 (S17) and the comparison result thereof is sent to the word-line-potential adjusting unit 12.

Then, in the word-line-potential adjusting unit 12, when the number of inversions of data read out from the memory cells MC does not match the expectation N3, the word line potential is adjusted (S18). At this time, the control signals S<0> to S<n> are input to the word line driver 4 from the word-line-potential adjusting unit 12. Then, the number of P-channel field-effect transistors to be turned on among the P-channel field-effect transistors P0 to Pn in FIG. 3 is changed based on the control signals S<0> to S<n>, so that the driving force of the word line driver 4 can be changed and thus the word line potential can be adjusted.

Thereafter, the processes at Steps S16 to S18 are repeated until the number of inversions of data read out from the memory cells MC matches the expectation N3.

When the number of inversions of data read out from the memory cells MC matches the expectation N3, the values of the control signals S<0> to S<n> at the time are stored in the word-line-potential adjusting unit 12 (S19). Then, the values of the control signals S<0> to S<n> at the time are output to an external SRAM macro as a word line code CDE and the SRAM macro adjusts its own word line potential based on the word line code CDE, thereby enabling to correct the word line potential according to the manufacturing variations, the operating temperature, and the like of SRAMs.

The target value of the source potential SCFV is calculated so that a predetermined margin can be obtained based on the distribution of the number of data inversions of the memory cells MC with respect to the source potential SCFV, so that the word line potential can be adjusted to follow changes in the distribution of the static noise margin SNM of the memory cells MC. Therefore, even when the distribution of the static noise margin SNM of the memory cells MC changes due to change in chip temperature at the time of product shipment, aging, and the like, the word line potential can be corrected.

The word-line-potential control circuit in FIG. 1 may be mounted on the same chip as an external SRAM macro.

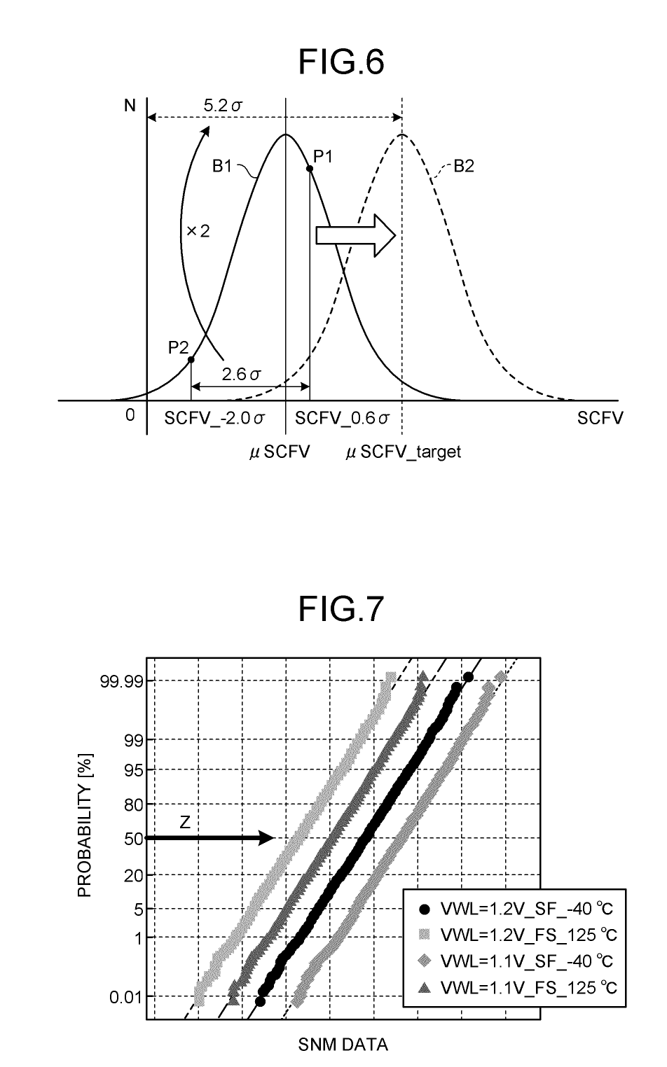

FIG. 6 is a diagram illustrating distributions of the number of data inversions N with respect to the source potential before and after word line potential adjustment in the word-line-potential control circuit in FIG. 1. In the example in FIG. 6, when the number of cells of the memory cell array 1 is 2K bits, the expectation N1 is set to 1486 (=2048(2K)×0.7257(0.6σ)) that is the number of inversions equivalent to 0.6σ, the expectation N2 is set to 46 (=2048(2K)×0.0228(−2.0σ)) that is the number of inversions equivalent to −2.0σ, and the expectation N3 is set to 1024 (=2048(2K)×0.5(0σ)) that is the number of inversions equivalent to 0σ.

In FIG. 6, the source potential SCFV is swept until the number of inversions of data read out from the memory cells MC in FIG. 1 reaches the number of inversions equivalent to 0.6σ to obtain a source potential SCFV_{—}0.6σ when the number of inversions of data read out from the memory cells MC reaches the number of inversions equivalent to 0.6σ. Moreover, the source potential SCFV is swept until the number of inversions of data read out from the memory cells MC in FIG. 1 reaches the number of inversions equivalent to −2.0σ to obtain a source potential SCFV_{—}−2.0σ when the number of inversions of data read out from the memory cells MC reaches the number of inversions equivalent to −2.0σ.

Then, extrapolation is performed based on a point P1 of the source potential SCFV_{—}0.6σ when the number of data inversions N is 0.6σ and a point P2 of the source potential SCFV_{—}−2.0σ when the number of data inversions N is −2.0σ, so that it is possible to obtain a distribution B1 of the number of data inversions N with respect to the source potential SCFV before word line potential adjustment.

Next, for example, in the case where the target yield is 5.2σ, μSCFV_target is calculated as μSCFV_target=(SCFV_{—}0.6σ−SCFV_{—}−2.0σ)×2+α=SCFV_{—}5.2σ based on the source potentials SCFV_{—}0.6σ and SCFV_{—}−2.0σ, where α is a margin.

Then, an average μSCFV of the source potential of a distribution B2 of the number of data inversions N with respect to the source potential SCFV after word line potential adjustment is set to become the source potential μSCFV_target, so that the yield 5.2σ can be satisfied.

The selection method of the two points P1 and P2 is explained. As the characteristics of the source potential SCFV, the source potential SCFV varies greatly at a point at which the number of data inversions N is small and the source potential SCFV is saturated at a point at which the number of data inversions N is large, so that the two points P1 and P2 to be selected are preferably close to the center of the distribution B1. However, because the source potential SCFV of the yield to be a target is extrapolated from these two points P1 and P2, variation can be suppressed by securing a large width between the two points P1 and P2 to be selected. Therefore, preferably, the two points P1 and P2 are close to the center of the distribution B1 and have a wide width therebetween, and as the points P1 and P2 satisfying the conditions, for example, two points of 0.6σ and −2.0σ can be selected.

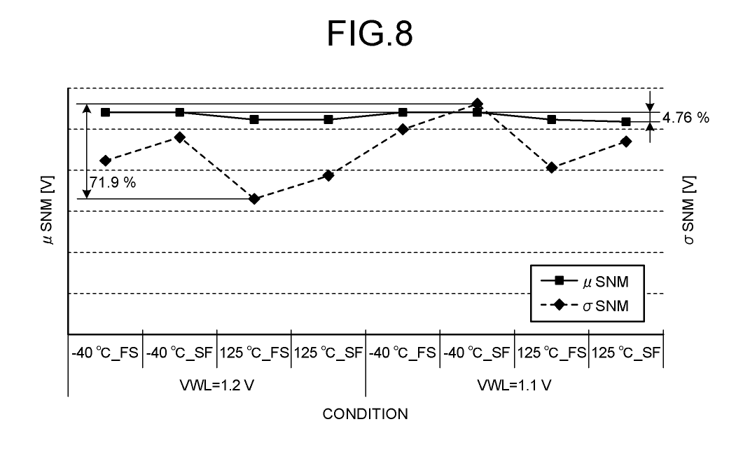

FIG. 7 is a diagram illustrating a relationship between a word line potential VWL, process conditions, and temperature of the word-line-potential control circuit in FIG. 1, and SNM data, and FIG. 8 is a diagram illustrating changes in μSNM and σSNM when the word line potential VWL, the process conditions, and the temperature of the word-line-potential control circuit in FIG. 1 are changed. FS indicates a case where an N-channel field-effect transistor is Vth fast and a P-channel field-effect transistor is Vth slow, and SF indicates a case where an N-channel field-effect transistor is Vth slow and a P-channel field-effect transistor is Vth fast.

In FIG. 7 and FIG. 8, a standardized variable Z of the static noise margin SNM largely depends on the change in the average μSNM of the static noise margin rather than the variance value σSNM of the static noise margin regardless of the word line potential VWL, the process conditions, and the temperature conditions, and the effect of the variance value σ on the static noise margin distribution is small.

Therefore, change in shape of the static noise margin distribution is small, and the shape of the static noise margin distribution can be obtained by performing the processes at S1 to S12 in FIG. 5 only once. Because the correlation between the static noise margin SNM and the source potential SCFV is high, the same thing as the static noise margin SNM can be said for the source potential SCFV.

### Second Embodiment

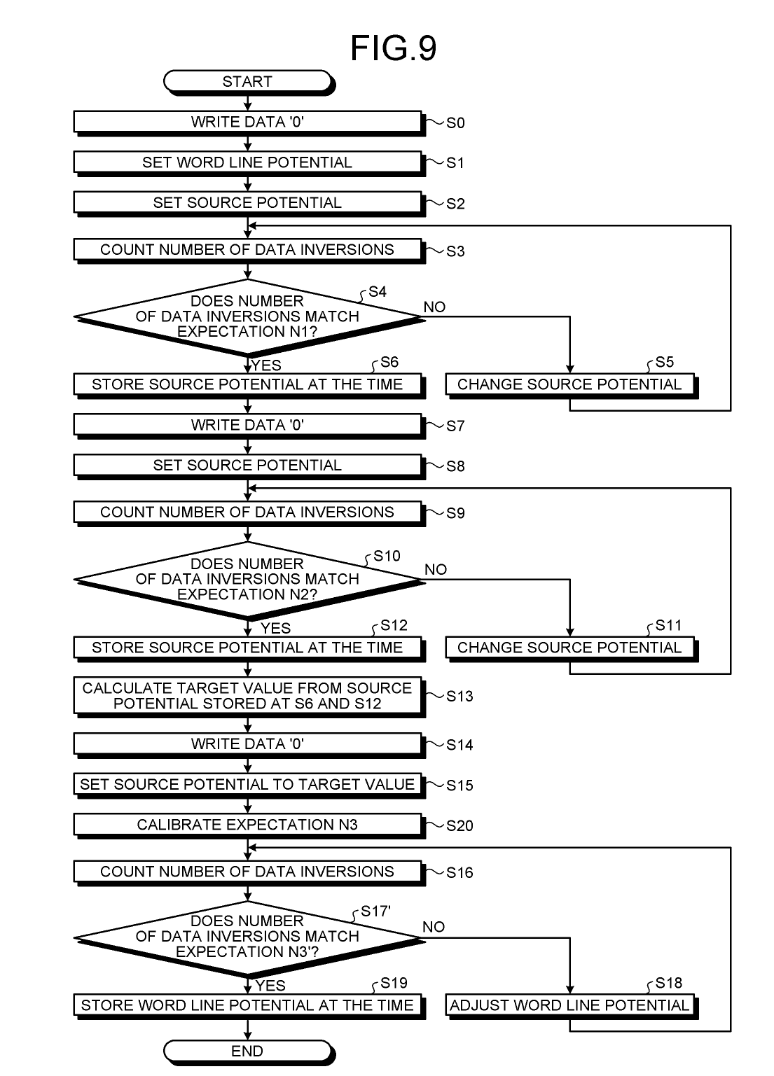

FIG. 9 is a flowchart illustrating an operation of a word-line-potential control circuit according to the second embodiment.

In FIG. 9, S0 to S15 are similar to the processes in FIG. 5. At this time, the number of cells to be a count target in the comparator 11 can be set to, for example, 2K.

Next, for reducing the number of cells to be a count target in the comparator 11 at S16 and thereafter, the expectation N3 is calibrated (S20). In this calibration, error in the average caused due to reduction in the number of cells to be a count target in the comparator 11 is corrected. At this time, the number of cells to be a count target in the comparator 11 can be set to, for example, 128 bits.

Next, data is read out from part of the memory cells MC of the memory cell array 1 via the read/write circuit 7 in FIG. 1. Then, in the counter 8, the number of inversions of data read out from the memory cells MC is counted (S16) and is output to the comparator 11. Then, in the comparator 11, the number of inversions of data read out from part of the memory cells MC of the memory cell array 1 is compared with a calibrated expectation N3′ (S17′) and the comparison result thereof is sent to the word-line-potential adjusting unit 12.

Then, in the word-line-potential adjusting unit 12, when the number of inversions of data read out from part of the memory cells MC of the memory cell array 1 does not match the calibrated expectation N3′, the word line potential is adjusted (S18). Thereafter, the processes at Steps S16 to S18 are repeated until the number of inversions of data read out from part of the memory cells MC of the memory cell array 1 matches the calibrated expectation N3′.

The number of the memory cells MC from which data is read out at the time of word line potential adjustment can be reduced by reducing the number of cells to be a count target in the comparator 11 at S16 and thereafter, so that the word-line-potential adjustment time can be shortened.

### Third Embodiment

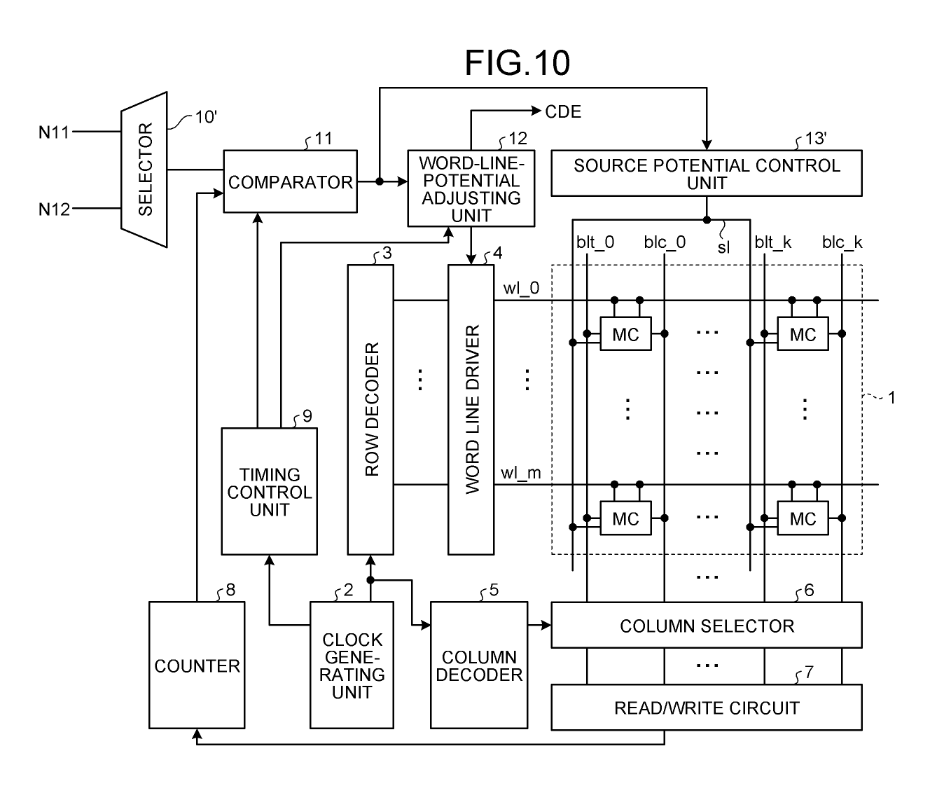

FIG. 10 is a block diagram illustrating a schematic configuration of a word-line-potential control circuit according to the third embodiment.

In FIG. 10, in this word-line-potential control circuit, a selector 10′ and a source potential control unit 13′ are provided instead of the selector 10 and the source potential control unit 13 in the word-line-potential control circuit in FIG. 1.

The selector 10′ can switch between expectations N11 and N12 and output the expectation to the comparator 11. The source potential control unit 13′ can control the source potential SCFV of the memory cells MC via the source line sl. The source potential control unit 13′ can obtain the distribution of the number of data inversions with respect to the source potential SCFV from one point at which the number of inversions of data read out from the memory cells MC matches the expectation N11 when the source potential SCFV is swept.

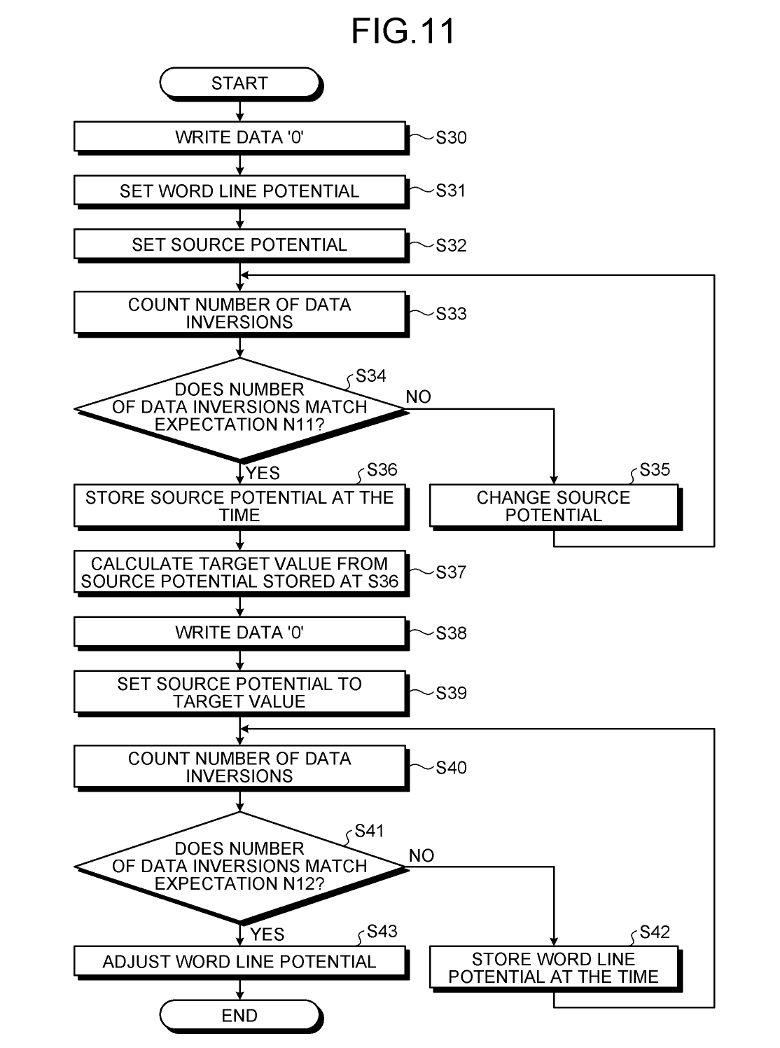

FIG. 11 is a flowchart illustrating an operation of the word-line-potential control circuit in FIG. 10.

In FIG. 11, data ‘0’ is written in all of the memory cells MC of the memory cell array 1 via the read/write circuit 7 in FIG. 10 (S30). Next, in the word-line-potential adjusting unit 12, the word line potential is set to the initial value (S31). Next, in the source potential control unit 13, the source potential SCFV is set to the initial value (S32).

Next, data is read out from all of the memory cells MC of the memory cell array 1 via the read/write circuit 7 in FIG. 10. Then, in the counter 8, the number of inversions of data read out from the memory cells MC is counted (S33) and is output to the comparator 11. Moreover, in the selector 10′ in FIG. 10, the expectation N11 is selected and is output to the comparator 11. Then, in the comparator 11, the number of inversions of data read out from the memory cells MC is compared with the expectation N11 (S34) and the comparison result thereof is sent to the source potential control unit 13′.

Then, in the source potential control unit 13′, when the number of inversions of data read out from the memory cells MC does not match the expectation N11, the source potential SCFV is changed (S35). Thereafter, the processes at Steps S33 to S35 are repeated until the number of inversions of data read out from the memory cells MC matches the expectation N11.

Then, when the number of inversions of data read out from the memory cells MC matches the expectation N11, the source potential SCFV at the time is stored (S36).

Next, the distribution of the number of data inversions of the memory cells MC with respect to the source potential SCFV is estimated based on the value of the source potential SCFV stored at Step S36. Then, the target value of the source potential SCFV is calculated so that a predetermined margin is obtained based on the distribution of the number of data inversions of the memory cells MC with respect to the source potential SCFV (S37).

Next, data ‘0’ is written in all of the memory cells MC of the memory cell array 1 via the read/write circuit 7 in FIG. 10 (S38). Next, in the source potential control unit 13′, the source potential SCFV is set to the target value (S39).

Next, data is read out from all of the memory cells MC of the memory cell array 1 via the read/write circuit 7 in FIG. 10. Then, in the counter 8, the number of inversions of data read out from the memory cells MC is counted (S40) and is output to the comparator 11. Moreover, in the selector 10′ in FIG. 10, the expectation N12 is selected and is output to the comparator 11. Then, in the comparator 11, the number of inversions of data read out from the memory cells MC is compared with the expectation N12 (S41) and the comparison result thereof is sent to the word-line-potential adjusting unit 12.

Then, in the word-line-potential adjusting unit 12, when the number of inversions of data read out from the memory cells MC does not match the expectation N12, the word line potential is adjusted (S42). Thereafter, the processes at Steps S40 to S42 are repeated until the number of inversions of data read out from the memory cells MC matches the expectation N12.

Then, when the number of inversions of data read out from the memory cells MC matches the expectation N12, the values of the control signals S<0> to S<n> at the time are stored in the word-line-potential adjusting unit 12 (S43). Then, the values of the control signals S<0> to S<n> at the time are output to an external SRAM macro as the word line code CDE and the SRAM macro adjusts its own word line potential based on the word line code CDE, thereby enabling to correct the word line potential according to the manufacturing variations, the operating temperature, and the like of SRAMs.

For example, when the number of cells of the memory cell array 1 is 2K bits, the expectation N11 can be set to 1024 (=2048(2K)×0.5(0σ)) that is the number of inversions equivalent to 0σ and the expectation N12 can be set to 83 (=2048(2K)×0.0409(−1.74σ)) that is the number of inversions equivalent to −1.74σ.

The source potential SCFV is swept until the number of inversions of data read out from the memory cells MC in FIG. 10 reaches the number of inversions equivalent to 0σ to obtain a source potential SCFV_{—}0σ when the number of inversions of data read out from the memory cells MC reaches the number of inversions equivalent to 0σ.

Next, for example, in the case where the target yield is 5.2σ, SCFV_comp is calculated as SCFV_comp=(SCFV_{—}0σ×2/3+α) based on the source potential SCFV_{—}0σ, where α is margin.

At this time, for the target yield to satisfy 5.2σ, the source potential SCFV_comp needs to be the source potential SCFV of −1.74σ. Therefore, the source potential SCFV is set to SCFV_comp and the word line potential is adjusted so that the number of inversions of −1.74σ can be obtained, so that the target yield 5.2σ can be satisfied.

There is also a method other than counting the number of inversions of 0σ for monitoring 0σ. For example, parallel replica cells of a few Kb are prepared and an internal node is short-circuited. Thereafter, the source potential SCFV is swept and the source potential SCFV when the inversion is obtained is set to SCFV_{—}0σ.

Moreover, in the above embodiments, explanation is given for the method of adjusting the word line potential based on the distribution of the number of data inversions N with respect to the source potential SCFV, however, for example, it is applicable to use for control of a well bias or control of a cell power source.

Furthermore, in the embodiments of the present invention, the following aspect may be included. Specifically, a characteristic control unit sets a third control value based on a first control value and a second control value, and the word-line-potential adjusting unit adjusts the potential of the word line so that the count result matches the third control value when the characteristics of the memory cells are controlled based on the third control value. Alternatively, the word-line-potential adjusting unit sets the number of memory cells to be a count target when adjusting the potential of the word line to be different from the number of memory cells to be a count target when specific characteristics of the memory cells are controlled, and the characteristic control unit corrects the third expectation according to change in the number of the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A word-line-potential control circuit comprising:
a memory cell array in which a plurality of memory cells is arranged in an array;
a read circuit that reads out data from the memory cells;
a word line driver that drives a word line of the memory cells;
a characteristic control unit that controls a specific characteristic of the memory cells; and
a word-line-potential adjusting unit that adjusts a potential of the word line based on a distribution of the characteristic when the specific characteristic of the memory cells is controlled.

2. The word-line-potential control circuit according to claim 1, further comprising:
a counter that counts number of inversions of data read out from the memory cells when the specific characteristic of the memory cells is controlled; and
a comparator that compares a count result by the counter with an expectation, wherein
the characteristic control unit estimates the distribution of the characteristic based on the characteristic of the memory cells when the count result matches the expectation.

3. The word-line-potential control circuit according to claim 2, wherein
a first expectation and a second expectation are provided as the expectation, and
the characteristic control unit estimates the distribution of the characteristic based on a first control value of the characteristic of the memory cells when the count result matches the first expectation and a second control value of the characteristic of the memory cells when the count result matches the second expectation.

4. The word-line-potential control circuit according to claim 3, wherein the first expectation and the second expectation are set so that an average of the first control value and the second control value becomes equal to or less than an average of the distribution of the characteristic.

5. The word-line-potential control circuit according to claim 4, wherein
the characteristic control unit sets a third control value based on the first control value and the second control value, and
the word-line-potential adjusting unit adjusts the potential of the word line so that the count result matches the third expectation when the characteristic of the memory cells is controlled based on the third control value.

6. The word-line-potential control circuit according to claim 5, wherein
the word-line-potential adjusting unit sets number of memory cells to be a count target when adjusting the potential of the word line to be different from number of memory cells to be a count target when the specific characteristic of the memory cells is controlled, and
the characteristic control unit corrects the third expectation according to change in the number of the memory cells.

7. The word-line-potential control circuit according to claim 1, wherein the specific characteristic of the memory cells is a stability when data is stored in the memory cells.

8. The word-line-potential control circuit according to claim 6, wherein a static noise margin is used as an index indicating the stability of the memory cells.

9. The word-line-potential control circuit according to claim 8, wherein
the memory cell is an SRAM cell, and
the characteristic control unit is a source potential control unit that controls a source potential of the SRAM cell.

10. The word-line-potential control circuit according to claim 9, further comprising a row decoder that makes to perform a row selection of the memory cells.

11. The word-line-potential control circuit according to claim 10, further comprising:
a bit line that perform a column selection of the memory cells; and
a column selector that connects a bit line made to perform the column selection to the read circuit.

12. The word-line-potential control circuit according to claim 11, wherein
the memory cells includes
a first CMOS inverter in which a first drive transistor and a first load transistor are connected in series with each other,
a second CMOS inverter in which a second drive transistor and a second load transistor are connected in series with each other,
a first transfer transistor connected between a first storage node provided at a connection point of the first drive transistor and the first load transistor and a first bit line, and
a second transfer transistor connected between a second storage node provided at a connection point of the second drive transistor and the second load transistor and a second bit line,
output and input of the first CMOS inverter and the second CMOS inverter are cross-coupled to each other,
a gate of the first transfer transistor and a gate of the second transfer transistor are connected to the word line, and
the source potential control unit controls a source potential of the first drive transistor or a source potential of the second drive transistor.

13. The word-line-potential control circuit according to claim 12, wherein
the word line driver includes
a CMOS inverter provided for each row, and
a plurality of field-effect transistors connected in parallel with each other to an output side of the CMOS inverter, and
the word-line-potential adjusting unit changes a driving force of the word line driver by changing number of field-effect transistors to be turned on among the field-effect transistors based on the distribution of the characteristic when the specific characteristic of the memory cells is controlled.

14. A word-line-potential control circuit comprising:
a memory cell array in which a plurality of SRAM cells is arranged in an array;
a read circuit that reads out data from the SRAM cells;
a word line driver that drives a word line of the SRAM cells;
a source potential control unit that controls a source potential of the SRAM cells; and
a word-line-potential adjusting unit that adjusts a potential of the word line based on a distribution of number of inversions of data stored in the SRAM cells when the source potential of the SRAM cells is controlled.

15. The word-line-potential control circuit according to claim 14, further comprising:
a counter that counts number of inversions of data read out from the SRAM cells when the source potential of the SRAM cells is controlled; and
a comparator that compares a count result by the counter with an expectation, wherein
the source potential control unit estimates the distribution of the number of inversions of data based on number of inversions of data in the SRAM cells when the count result matches the expectation.

16. The word-line-potential control circuit according to claim 15, wherein
the source potential control unit includes
a source-potential sweep unit that sweeps the source potential of the SRAM cells,
a register that stores a value of the source potential when the count result by the counter matches the expectation, and
an extrapolation calculation unit that estimates the distribution of the number of data inversions of the SRAM cells with respect to the source potential based on the value of the source potential stored in the register.

17. The word-line-potential control circuit according to claim 16, wherein the source potential control unit estimates the distribution from number of data inversions of the SRAM cells with respect to a source potential for two points when the source potential is swept.

18. The word-line-potential control circuit according to claim 16, wherein the source potential control unit estimates the distribution from number of data inversions of the SRAM cells with respect to a source potential for one point when the source potential is swept.

19. The word-line-potential control circuit according to claim 17, wherein the source potential control unit calculates a target value of the source potential so that a predetermined margin is obtained based on the distribution of the number of data inversions of the SRAM cells.

20. The word-line-potential control circuit according to claim 19, wherein the word-line-potential adjusting unit adjusts the word line potential so that the number of data inversions of the SRAM cells matches the expectation when the source potential is set to the target value.
